(19) United States
(12) Patent Application Publication
(10) Pub. No.: US 2026/0269787 A1
(43) Pub. Date: Sep. 10, 2026

(54) TRACKER CIRCUIT AND RADIO FREQUENCY CIRCUIT

(71) Applicant: Murata Manufacturing Co., Ltd., Nagaokakyo-shi (JP)

(72) Inventors: Muneharu KATO, Nagaokakyo-shi (JP); Kouji YAMAGUCHI, Nagaokakyo-shi (JP); Seiko NETSU, Nagaokakyo-shi (JP); Atsushi HIRONO, Nagaokakyo-shi (JP)

(21) Appl. No.: 19/662,111

(22) Filed: Apr. 29, 2026

Related U.S. Application Data
(63) Continuation of application No. PCT/JP2024/030292, filed on Aug. 26, 2024.

(30) Foreign Application Priority Data
Dec. 22, 2023 (JP) 2023-216925

(51) Int. Cl. H03F 1/02; H03F 3/00

(52) U.S. Cl. CPC H03F 1/0227; H03F 3/005; H03F 2200/451; H03F 2200/511

(57) ABSTRACT

A tracker circuit is provided that includes multiple control input terminals configured to receive respective multiple DCL signals, a switched-capacitor circuit configured to generate multiple discrete voltages from an input voltage, a supply modulator configured to selectively output at least one of the multiple discrete voltages to a power amplifier based on the multiple DCL signals with a first delay, a supply modulator configured to selectively output at least one of the multiple discrete voltages to a power amplifier based on the multiple DCL signals, and a delay circuit configured to generate the first delay.

### CROSS REFERENCE TO RELATED APPLICATIONS

This application is a continuation of International Application No. PCT/JP 2024/030292, filed Aug. 26, 2024, which claims priority to Japanese Patent Application No. 2023-216925, filed Dec. 22, 2023, the entire contents of each of which are hereby incorporated by reference in their entirety.

### TECHNICAL FIELD

The present disclosure relates to a tracker circuit and a radio frequency circuit.

### BACKGROUND

Power efficiency has been intended to be improved by applying Envelope Tracking (ET) to a power amplifier circuit in recent years. For example, U.S. Pat. No. 9,755,672 discloses a Digital Envelope Tracking (D-ET) mode in which multiple discrete voltages are selectively supplied to power amplifiers based on an envelope signal.

### SUMMARY OF INVENTION

However, in the D-ET mode, when power supply voltage is concurrently supplied to multiple power amplifiers, trackability of the power supply voltage to the envelope of a radio frequency signal may be reduced to reduce the power efficiency.

Accordingly, the exemplary aspects of the present disclosure provide a tracker circuit and a radio frequency circuit, which are capable of improving the power efficiency in the D-ET mode.

According to an exemplary aspect, a tracker circuit includes multiple external connection terminals configured to receive multiple digital control level signals (e.g., each external connection terminal receives a respective digital control level signal), a switched-capacitor circuit (e.g., including at least one switch) configured to generate multiple discrete voltages from an input voltage, a first supply modulator configured to selectively output at least one of the multiple discrete voltages as a first power supply to a first power amplifier based on the multiple digital control level signals with a first delay, a second supply modulator configured to selectively output at least one of the multiple discrete voltages as a second power supply to a second power amplifier based on the multiple digital control level signals, and a first delay circuit configured to generate the first delay.

In another exemplary aspect of the disclosure, a radio frequency circuit includes multiple first external connection terminals configured to receive multiple respective discrete voltages (e.g., each first external connection terminal receives a respective discrete voltage), multiple second external connection terminals configured to receive multiple respective digital control level signals (e.g., each second external connection terminal receives a respective digital control level signal), a first power amplifier and a second power amplifier, a first supply modulator configured to selectively output at least one of the multiple discrete voltages as a first power supply to the first power amplifier based on the multiple digital control level signals with a first delay, a second supply modulator configured to selectively output at least one of the multiple discrete voltages as a second power supply to the second power amplifier based on the multiple digital control level signals, and a first delay circuit configured to generate the first delay.

According to the exemplary aspects of the present disclosure, power efficiency in the D-ET mode can be improved.

### BRIEF DESCRIPTION OF DRAWINGS

FIG. 1A is a graph indicating an example of transition of power supply voltage in an Average Power Tracking (APT) mode.

FIG. 1B is a graph indicating an example of transition of the power supply voltage in an Analog Envelope Tracking (A-ET) mode.

FIG. 1C is a graph indicating an example of transition of the power supply voltage in a Digital Envelope Tracking (D-ET) mode.

FIG. 2 is a diagram illustrating the circuit configuration of a communication device according to a first exemplary embodiment.

FIG. 3 is a diagram illustrating the circuit configuration of a tracker circuit according to the first exemplary embodiment.

FIG. 4 is a diagram illustrating the circuit configuration of a digital control circuit according to the first exemplary embodiment.

FIG. 5 is a diagram illustrating the circuit configuration of a communication device according to a modification of the first exemplary embodiment.

FIG. 6 is a diagram illustrating the circuit configuration of a communication device according to a second exemplary embodiment.

FIG. 7 is a diagram illustrating the circuit configuration of a communication device according to a third exemplary embodiment.

### DETAILED DESCRIPTION OF EXEMPLARY EMBODIMENTS

Exemplary embodiments of the present disclosure will herein be described in detail with reference to the drawings. All the exemplary embodiments described below indicate comprehensive or specific examples. Numerical values, shapes, materials, components, the arrangement of the components, the connection mode of the components, and so on, which are indicated in the exemplary embodiments described below, are only examples and are not intended to limit the present disclosure.

The respective drawings are schematic diagrams appropriately subjected to emphasis, omission, or adjustment of ratios in order to describe the present disclosure. The respective drawings are not necessarily strictly illustrated and may be different from the actual shapes, positional relationship, and ratios. The same reference numerals and letters are added in the respective drawings to identify substantially the same components and a duplicated description of such components may be omitted or simplified.

In circuit configurations, the term “connected” includes not only direct connection with a connection terminal and/or a wiring conductor but also electrical connection via another circuit element. The expression “A is switchably connected to B” indicates that connection and non-connected between A and B are switchable and indicates that A is connected to B via a switch. The expression “A is connected to B” includes “A is switchably connected to B”. The expression “C is connected between A and B” indicates that one end of C is connected to A and the other end of C is connected to B and indicates that C is connected in series to the path between A and B. The expression “path between A and B” refers to a path composed of a conductor with which A is electrically connected to B.

In the following description, a “terminal” refers to a point at which a conductor in an element terminates. When impedance of a conductor between elements is sufficiently low, the terminal is interpreted not only as a single point but also as an arbitrary point on the conductor between the elements or the entire conductor.

Terms, such as “parallel” and “vertical”, indicating the relationship between elements, terms, such as a “rectangle”, indicating the shapes of elements, and numerical ranges do not represent only strict meanings but also refer to inclusion of substantially the same range, for example, an error of about a few percents.

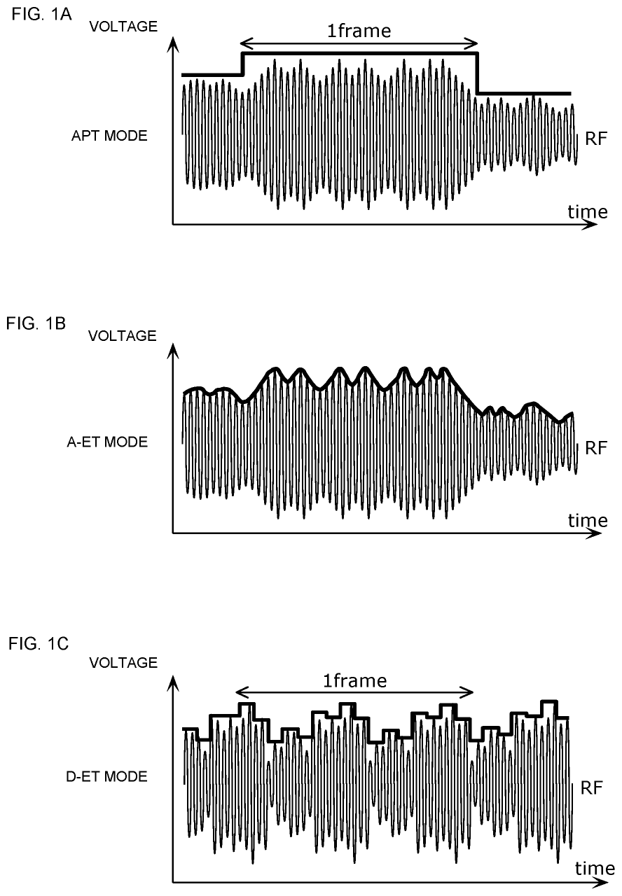

Tracking modes in which power supply voltage that is dynamically adjusted over time based on a radio frequency signal is supplied to a power amplifier are described as techniques to amplify the radio frequency signal with high efficiency. The tracking mode is a mode in which the power supply voltage to be applied to the power amplifier is dynamically adjusted. Several kinds of the tracking modes are used. Here, an Average Power Tracking (APT) mode, an Analog Envelope Tracking (A-ET) mode, and a Digital Envelope Tracking (D-ET) mode will now be described with reference to FIG. 1A, FIG. 1B, and FIG. 1C, respectively. Referring to FIG. 1A, FIG. 1B, and FIG. 1C, the horizontal axis represents time and the vertical axis represents voltage. Bold solid lines represent power supply voltage and thin solid lines (waveforms) represent modulation signal.

FIG. 1A is a graph indicating an example of transition of the power supply voltage in the APT mode. In the APT mode in FIG. 1A, the power supply voltage is varied to multiple discrete voltage levels in unit of frames based on average power.

For purposes of this disclosure, a frame refers to a unit composing the radio frequency signal (e.g., the modulation signal). For example, in 5th Generation New Radio (5GNR) and Long Term Evolution (LTE), the frame includes ten sub-frames, each sub-frame includes multiple slots, and each slot includes multiple symbols. The sub-frame length is one millisecond and the frame length is ten milliseconds.

The mode in which the voltage level is varied in units of frames or in units greater than one frame based on the average power is called the APT mode, which is discriminated from a mode in which the voltage level is varied in units smaller than one frame (for example, in units of sub-frames, in units of slots, or in units of symbols). For example, the mode in which the voltage level is varied in units of symbols is called a Symbol Power Tracking (SPT) mode, which is discriminated from the APT mode.

FIG. 1B is a graph indicating an example of transition of the power supply voltage in the A-ET mode. In the A-ET mode, the power supply voltage is continuously varied based on an envelope signal to track the envelope of the modulation signal.

The envelope signal is a signal indicating the envelope of the modulation signal. The envelope value is represented by, for example, a square root of (I²+Q²). Here, (I, Q) represents a constellation point. The constellation point is a point that represents a signal subjected to digital modulation on a constellation diagram. (I, Q) is determined by a baseband integrated circuit (BBIC) based on, for example, transmission information.

FIG. 1C is a graph indicating an example of transition of the power supply voltage in the D-ET mode. In the D-ET mode, the power supply voltage is varied to multiple discrete voltage levels in one frame based on the envelope signal to track the envelope of the modulation signal. In other words, in the D-ET mode, the power supply voltage is varied at time intervals shorter than those in the APT.

### First Exemplary Embodiment

A first exemplary embodiment will now be described.

### 1.1 Circuit Configuration of Communication Device 3

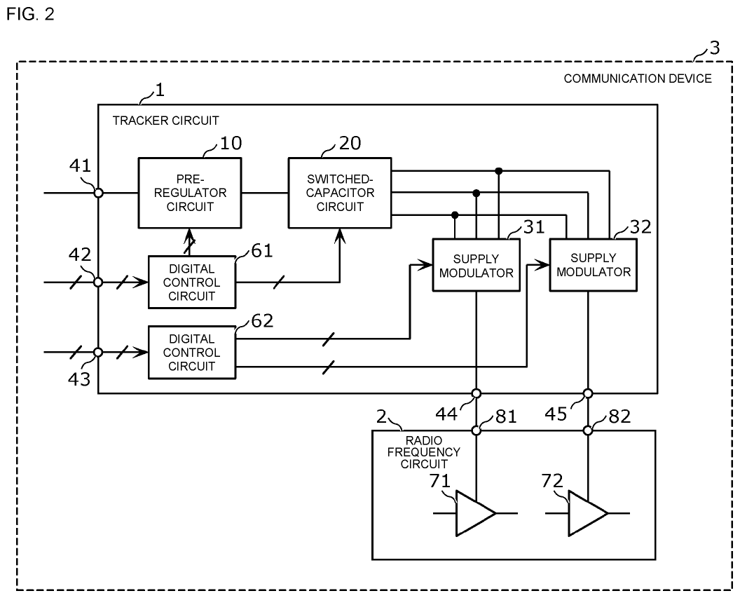

An exemplary circuit configuration of a communication device 3 according to the present exemplary embodiment will be described with reference to FIG. 2. FIG. 2 is a diagram illustrating the circuit configuration of the communication device 3 according to the present exemplary embodiment.

FIG. 2 illustrates an exemplary circuit configuration and the communication device 3 may be mounted using any of a variety of circuit implementation and various circuit techniques. Accordingly, the description of the communication device 3 provided below should not be limitedly interpreted.

The communication device 3 according to the present exemplary embodiment is usable for provision of wireless connection. For example, the communication device 3 is configured to be mounted in user equipment (UE) in a cellular network of mobile phones, smartphones, tablet computers, wearable devices, and so on. In another example, mounting of the communication device 3 enables the wireless connection to be provided to an Internet of Things (IoT) sensor device, a medical-health care device, a vehicle, an unmanned aerial vehicle (UAV) (a so-called drone), an automated guided vehicle (AGV). In another example, mounting of the communication device 3 enables the wireless connection to be provided at a wireless access point or a wireless hot spot.

As illustrated in FIG. 2, the communication device 3 includes a tracker circuit 1 and a radio frequency circuit 2.

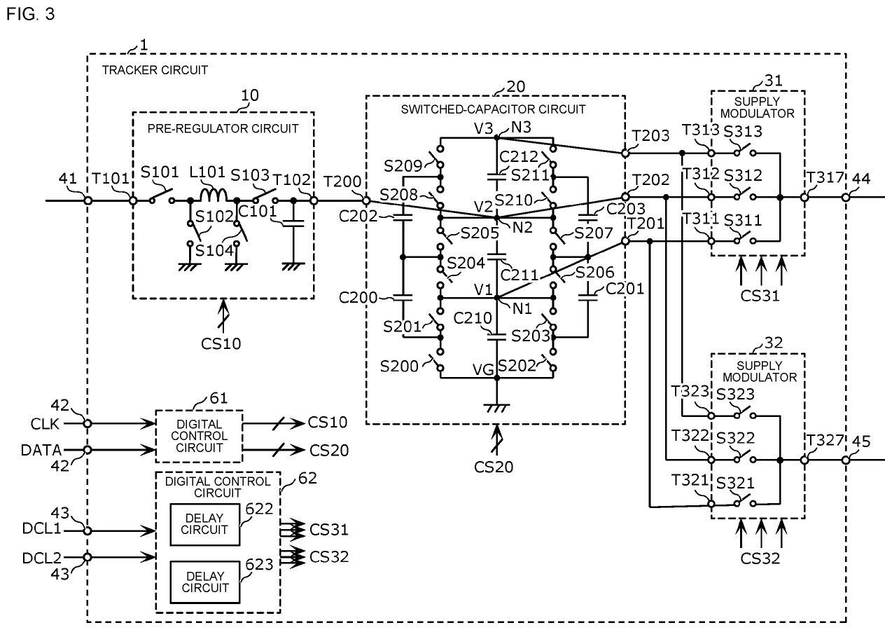

The tracker circuit 1 is configured to concurrently supply power supply voltage to power amplifiers 71 and 72 in the D-ET mode. The tracker circuit 1 may supply the power supply voltage to the power amplifiers 71 and 72 in the APT mode. The tracker circuit 1 is configured to be mounted on one semiconductor integrated circuit and may be called a power management integrated circuit (PMIC). The respective circuits and the respective terminals in the tracker circuit 1 will be described below with reference to FIG. 3.

The radio frequency circuit 2 is configured to up-convert an intermediate frequency (IF) signal or a baseband signal, which is supplied from the outside of the radio frequency circuit 2, to generate two radio frequency signals in a certain band. In addition, the radio frequency circuit 2 is configured to amplify the generated two radio frequency signals to output the amplified radio frequency signals to one or more antennas (not illustrated). The radio frequency circuit 2 is configured to be mounted on one semiconductor integrated circuit and may be called a radio frequency integrated circuit (RFIC).

In some examples, the radio frequency circuit 2 includes the power amplifiers 71 and 72 and power supply voltage terminals 81 and 82.

The power supply voltage terminal 81 is an external connection terminal through which the power supply voltage used in the power amplifier 71 is received from the tracker circuit 1. The power supply voltage terminal 81 is connected to an output terminal 44 of the tracker circuit 1 outside the radio frequency circuit 2 and is connected to the power amplifier 71 inside the radio frequency circuit 2.

The power supply voltage terminal 82 is an external connection terminal through which the power supply voltage used in the power amplifier 72 is received from the tracker circuit 1. The power supply voltage terminal 82 is connected to an output terminal 45 of the tracker circuit 1 outside the radio frequency circuit 2 and is connected to the power amplifier 72 inside the radio frequency circuit 2.

The power amplifier 71 is configured to amplify the radio frequency signal in the certain band using the power supply voltage supplied from a supply modulator 31 via the output terminal 44 and the power supply voltage terminal 81.

The power amplifier 72 is configured to amplify the radio frequency signal in the certain band using the power supply voltage supplied from a supply modulator 32 via the output terminal 45 and the power supply voltage terminal 82.

The certain band is a frequency band for a communication system that is built using Radio Access Technology (RAT) and is defined in advance by a standardizing body and the like (for example, 3rd Generation Partnership Project (3GPP) (registered trademark), Institute of Electrical and Electronics Engineers (IEEE), and the like). Examples of the communication system include a 5GNR system, an LTE system, a Wireless Local Area Network (WLAN) system, and so on.

In the present exemplary embodiment, the frequency band of Frequency Range 2 (FR2) of the 5GNR is used as the certain band. In this case, the two radio frequency signals amplified by the radio frequency circuit 2 may be output to two antennas corresponding to different two polarization directions. At this time, the two antennas may be realized by one patch antenna.

The circuit configuration of the communication device 3 illustrated in FIG. 2 is only an example and the circuit configuration of the communication device 3 is not limited to this. For example, the communication device 3 may include an IF signal processing circuit that performs signal processing using an intermediate frequency band lower than the band of the radio frequency signal and/or a baseband signal processing circuit that performs signal processing using a frequency band lower than the intermediate frequency band.

### 1.2 Circuit Configuration f Tracker Circuit 1

An exemplary circuit configuration of the tracker circuit 1 will now be described with reference to FIG. 2 and FIG. 3. FIG. 3 is a diagram illustrating the circuit configuration of the tracker circuit 1 according to the present exemplary embodiment.

FIG. 2 and FIG. 3 illustrate exemplary circuit configurations and the tracker circuit 1 may be mounted using any of a variety of circuit implementation and various circuit techniques. Accordingly, the description of the respective circuits provided below should not be limitedly interpreted.

As illustrated in FIG. 2 and FIG. 3, the tracker circuit 1 includes a pre-regulator circuit 10, a switched-capacitor circuit 20, the supply modulators 31 and 32, an input terminal 41, multiple control input terminals 42 and 43, the output terminals 44 and 45, and digital control circuits 61 and 62.

The input terminal 41 is an external connection terminal through which direct current voltage is received from a direct current power source (not illustrated). The input terminal 41 is connected to the direct current power source outside the tracker circuit 1 and is connected to the pre-regulator circuit 10 inside the tracker circuit 1.

The multiple control input terminals 42 are multiple external connection terminals through which serial data signals for controlling the pre-regulator circuit 10 and the switched-capacitor circuit 20 are received from the outside of the tracker circuit 1. The multiple control input terminals 42 are connected to the digital control circuit 61 inside the tracker circuit 1.

The multiple control input terminals 43 are multiple external connection terminals through which the respective multiple Digital Control Level (DCL) signals for controlling the supply modulators 31 and 32 are received from the outside of the tracker circuit 1. The multiple control input terminals 43 are connected to the digital control circuit 62 inside the tracker circuit 1.

The output terminal 44 is an external connection terminal through which the power supply voltage is supplied to the power amplifier 71. The output terminal 44 is connected to the power supply voltage terminal 81 of the radio frequency circuit 2 outside the tracker circuit 1 and is connected to the supply modulator 31 inside the tracker circuit 1.

The output terminal 45 is an external connection terminal through which the power supply voltage is supplied to the power amplifier 72. The output terminal 45 is connected to the power supply voltage terminal 82 of the radio frequency circuit 2 outside the tracker circuit 1 and is connected to the supply modulator 32 inside the tracker circuit 1.

The pre-regulator circuit 10 may be called a magnetic regulator or a direct current (DC)-DC converter. In the present exemplary embodiment, the pre-regulator circuit 10 is a one-input one-output buck boost converter and is configured to conver the direct current voltage into adjustment voltage. The pre-regulator circuit 10 may be a buck converter or a boost converter. The pre-regulator circuit 10 is configured to vary the adjustment voltage based on the serial data signals received through the multiple control input terminals 42. A detailed circuit configuration of the pre-regulator circuit 10 will be described below. Part of the pre-regulator circuit 10 or the entire pre-regulator circuit 10 is not necessarily included in the tracker circuit 1.

The switched-capacitor circuit 20 is configured to generate multiple discrete voltages V1, V2, and V3 based on the adjustment voltage supplied from the pre-regulator circuit 10. A detailed circuit configuration of the switched-capacitor circuit 20 will be described below. Part of the switched-capacitor circuit 20 is not necessarily included in the tracker circuit 1.

The supply modulators 31 and 32 are examples of a first supply modulator and a second supply modulator, respectively. The supply modulators 31 and 32 are configured to selectively output at least one of the multiple discrete voltages generated by the switched-capacitor circuit 20 to the power amplifiers 71 and 72, respectively. In other words, the supply modulators 31 and 32 are configured to select at least one voltage from the multiple discrete voltages to supply the same at least one voltage that is selected to the power amplifiers 71 and 72. A detailed circuit configuration of the supply modulators 31 and 32 will be described below.

The digital control circuit 61 is configured to process the serial data signals (CLK and DATA) received through the multiple control input terminals 42 to generate multiple control signals CS10 and CS20 for controlling the pre-regulator circuit 10 and the switched-capacitor circuit 20, respectively. The multiple control signals CS10 are signals to control opening and closing of switches S101 to S104 included in the pre-regulator circuit 10. The multiple control signals CS20 are signals to control opening and closing of switches S200 to S211 included in the switched-capacitor circuit 20. Part of the digital control circuit 61 or the entire digital control circuit 61 is not necessarily included in the tracker circuit 1. A feedback signal for controlling the pre-regulator circuit 10 may be input into the digital control circuit 61.

For example, a source-synchronous digital control signal is used as the serial data signal. A clock-embedded digital control signal may be used as the serial data signal. In this case, the multiple control input terminals 42 may be one control input terminal 42. The digital control circuit 61 may generate multiple control signals for controlling the supply modulators 31 and/or 32.

Although one set of a clock signal (CLK) and a data signal (DATA) are commonly used in the pre-regulator circuit 10 and the switched-capacitor circuit 20 in the present exemplary embodiment, the signals used in the pre-regulator circuit 10 and the switched-capacitor circuit 20 are not limited to this. For example, one set of the clock signal and the data signal may be separately used in the pre-regulator circuit 10 and the switched-capacitor circuit 20.

The digital control circuit 62 is configured to process parallel data signals received through the multiple control input terminals 43 to generate multiple control signals CS31 and CS32. The multiple control signals CS31 are examples of multiple first control signals and are signals for controlling the supply modulator 31. The multiple control signals CS32 are examples of multiple second control signals and are signals for controlling the supply modulator 32.

In the present exemplary embodiment, multiple DCL signals (DCL1 and DCL2) are used as the parallel data signals. The multiple DCL signals (DCL1 and DCL2) are generated based on the envelope signal of the radio frequency signal.

Each of the multiple DCL signals (DCL1 and DCL2) is a one-bit signal. Each of the multiple discrete voltages V1, V2, and V3 is represented by a combination of two one-bit signals. For example, V1, V2, and V3 are represented by “00”, “01”, and “10”, respectively. Gray code may be used for the representation of the voltage levels.

Although the two DCL signals are used for control of the supply modulators 31 and 32 in the present exemplary embodiment, the number of the DCL signals is not limited to this. For example, an arbitrary number of DCL signals, that is, one or three or more DCL signals may be used depending on the number of the voltage levels which each of the supply modulators 31 and 32 is configured to select. The parallel data signals used for control of the supply modulators 31 and 32 are not limited to the DCL signals.

### 1.3 Circuit Configuration of Pre-Regulator Circuit 10

An exemplary circuit configuration of the pre-regulator circuit 10 will now be described. The pre-regulator circuit 10 includes an input terminal T101, an output terminal T102, the switches S101 to S104, a power inductor L101, and a capacitor C101.

The input terminal T101 is a terminal through which the direct current voltage is received. The input terminal T101 is connected to the input terminal 41 of the tracker circuit 1 outside the pre-regulator circuit 10 and is connected to the switch S101 inside the pre-regulator circuit 10.

The output terminal T102 is a terminal through which the adjustment voltage is supplied to the switched-capacitor circuit 20. The output terminal T102 is connected to an input terminal T200 of the switched-capacitor circuit 20 outside the pre-regulator circuit 10 and is connected to the switch S103 inside the pre-regulator circuit 10.

The power inductor L101 is an inductor used for step-up and step-down of the direct current voltage. One end of the power inductor L101 is connected to the switches S101 and S102 and the other end of the power inductor L101 is connected to the switches S103 and S104.

The switch S101 is connected between the input terminal T101 and the one end of the power inductor L101. The switch S102 is connected between the one end of the power inductor L101 and ground. In this connection configuration, exclusively switching opening and closing of the switches S101 and S102 enables the direct current voltage received through the input terminal T101 to be stepped down.

The switch S103 is connected between the other end of the power inductor L101 and the output terminal T102. The switch S104 is connected between the other end of the power inductor L101 and the ground. In this connection configuration, exclusively switching opening and closing of the switches S103 and S104 enables the direct current voltage received through the input terminal T101 to be stepped up.

The capacitor C101 is connected between a path between the switch S103 and the output terminal T102 and the ground. In some examples, one of the two electrodes of the capacitor C101 is connected to the switch S103 and the output terminal T102 and the other of the two electrodes of the capacitor C101 is grounded.

The configuration of the pre-regulator circuit 10 illustrated in FIG. 3 is only an example and is not limited to this. For example, part of the switches S101 to S104 may be replaced with a diode. Part of the pre-regulator circuit 10 or the entire pre-regulator circuit 10 is not necessarily included in the tracker circuit 1.

### 1.4 Circuit Configuration of Switched-Capacitor Circuit 20

Next, an exemplary circuit configuration of the switched-capacitor circuit 20 will be described. The switched-capacitor circuit 20 has a ladder circuit configuration and is configured to generate the multiple discrete voltages V1, V2, and V3. In some examples, the switched-capacitor circuit 20 includes flying capacitors C200 to C203, smoothing capacitors C210 to C212, the switches S200 to S211, the input terminal T200, and output terminals T201 to T203. Energy and electric charge are input into a node N2 from the pre-regulator circuit 10 via the input terminal T200 and is extracted to the supply modulators 31 and 32 from nodes N1, N2, and N3 via the output terminals T201, T202, and T203, respectively.

The input terminal T200 is a terminal through which the adjustment voltage is received from the pre-regulator circuit 10. The input terminal T200 is connected to the pre-regulator circuit 10 outside the switched-capacitor circuit 20 and is connected to the node N2 inside the switched-capacitor circuit 20. The node to which the input terminal T200 is connected is not limited to the node N2. The input terminal T200 may be connected to any of the nodes N1, N2, and N3.

The output terminals T201, T202, and T203 are terminals through which the respective multiple discrete voltages V1, V2, and V3 are supplied to the supply modulators 31 and 32. The output terminals T201, T202, and T203 are connected to the supply modulators 31 and 32 outside the switched-capacitor circuit 20 and are connected to the nodes N1, N2, and N3, respectively, inside the switched-capacitor circuit 20.

The flying capacitors C200, C201, C202, and C203 may be called transfer capacitors and are used to step up and/or step down the adjustment voltage supplied from the pre-regulator circuit 10. For example, the flying capacitors C200, C201, C202, and C203 move the electric charge between the flying capacitors C200, C201, C202, and C203 and the nodes N1, N2, and N3, and the ground so as to keep V1, V2, and V3 meeting (V3−V2):(V2−V1):(V1−VG)=1:1:1 and V3>V2>V1>Vg at the three nodes N1, N2, and N3. Here, VG represents ground potential. (V3−V2):(V2−V1):(V1−VG) is not limited to 1:1:1 and may be designed to an arbitrary ratio (for example, 1:2:3 or the like).

One of the two electrodes of the flying capacitor C200 is connected to one end of the switch S200 and one end of the switch S201. The other of the two electrodes of the flying capacitor C200 is connected to one end of the switch S204 and one end of the switch S205.

One of the two electrodes of the flying capacitor C201 is connected to one end of the switch S202 and one end of the switch S203. The other of the two electrodes of the flying capacitor C201 is connected to one end of the switch S206 and one end of the switch S207.

One of the two electrodes of the flying capacitor C202 is connected to the one end of the switch S204 and the one end of the switch S205. The other of the two electrodes of the flying capacitor C202 is connected to one end of the switch S208 and one end of the switch S209.

One of the two electrodes of the flying capacitor C203 is connected to the one end of the switch S206 and the one end of the switch S207. The other of the two electrodes of the flying capacitor C203 is connected to one end of the switch S210 and one end of the switch S211.

The smoothing capacitors C210, C211, and C212 are used for holding and smoothing of the discrete voltages V1, V2, and V3 at the nodes N1, N2, and N3.

The smoothing capacitor C210 is connected between the node N1 and the ground. In some examples, one of the two electrodes of the smoothing capacitor C210 is connected to the node N1. The other of the two electrodes of the smoothing capacitor C210 is grounded.

The smoothing capacitor C211 is connected between the nodes N1 and N2. In some examples, one of the two electrodes of the smoothing capacitor C211 is connected to the node N2. The other of the two electrodes of the smoothing capacitor C211 is connected to the node N1.

The smoothing capacitor C212 is connected between the nodes N2 and N3. In some examples, one of the two electrodes of the smoothing capacitor C212 is connected to the node N3. The other of the two electrodes of the smoothing capacitor C212 is connected to the node N2.

The switch S200 is connected between the flying capacitor C200 and the ground. In some examples, the one end of the switch S200 is connected to one of the two electrodes of the flying capacitor C200. The other end of the switch S200 is grounded.

The switch S201 is connected between the flying capacitor C200 and the node N1. In some examples, the one end of the switch S201 is connected to one of the two electrodes of the flying capacitor C200. The other end of the switch S201 is connected to the node N1.

The switch S202 is connected between the flying capacitor C201 and the ground. In some examples, the one end of the switch S202 is connected to one of the two electrodes of the flying capacitor C201. The other end of the switch S202 is grounded.

The switch S203 is connected between the flying capacitor C201 and the node N1. In some examples, the one end of the switch S203 is connected to one of the two electrodes of the flying capacitor C201. The other end of the switch S203 is connected to the node N1.

The switch S204 is connected between the flying capacitors C200 and C202 and the node N1. In some examples, the one end of the switch S204 is connected to the other of the two electrodes of the flying capacitor C200 and one of the two electrodes of the flying capacitor C202. The other end of the switch S204 is connected to the node N1.

The switch S205 is connected between the flying capacitors C200 and C202 and the node N2. In some examples, the one end of the switch S205 is connected to the other of the two electrodes of the flying capacitor C200 and one of the two electrodes of the flying capacitor C202. The other end of the switch S205 is connected to the node N2.

The switch S206 is connected between the flying capacitors C201 and C203 and the node N1. In some examples, the one end of the switch S206 is connected to the other of the two electrodes of the flying capacitor C201 and one of the two electrodes of the flying capacitor C203. The other end of the switch S206 is connected to the node N1.

The switch S207 is connected between the flying capacitors C201 and C203 and the node N2. In some examples, the one end of the switch S207 is connected to the other of the two electrodes of the flying capacitor C201 and one of the two electrodes of the flying capacitor C203. The other end of the switch S207 is connected to the node N2.

The switch S208 is connected between the flying capacitor C202 and the node N2. In some examples, the one end of the switch S208 is connected to the other of the two electrodes of the flying capacitor C202. The other end of the switch S208 is connected to the node N2.

The switch S209 is connected between the flying capacitor C202 and the node N3. In some examples, the one end of the switch S209 is connected to the other of the two electrodes of the flying capacitor C202. The other end of the switch S209 is connected to the node N3.

The switch S210 is connected between the flying capacitor C203 and the node N2. In some examples, the one end of the switch S210 is connected to the other of the two electrodes of the flying capacitor C203. The other end of the switch S210 is connected to the node N2.

The switch S211 is connected between the flying capacitor C203 and the node N3. In some examples, the one end of the switch S211 is connected to the other of the two electrodes of the flying capacitor C203. The other end of the switch S211 is connected to the node N3.

Opening and closing of a first set of switches including the switches S200, S203, S204, S207, S208, and S211 is inversely switched with respect to opening and closing of a second set of switches including the switches S201, S202, S205, S206, S209, and S210 based on the multiple control signals CS20 from the digital control circuit 61.

In some examples, in a first phase, the first set of switches is closed and the second set of switches is opened. As a result, one of the two electrodes of the flying capacitor C200 is grounded. The other of the two electrodes of the flying capacitor C200, one of the two electrodes of the flying capacitor C201, and one of the two electrodes of flying capacitor C202 are connected to the node N1. The other of the two electrodes of the flying capacitor C201, the other of the two electrodes of flying capacitor C202, and one of the two electrodes of flying capacitor C203 are connected to the node N2. The other of the two electrodes of the flying capacitor C203 is connected to the node N3.

Conversely, in a second phase, the first set of switches is opened and the second set of switches is closed. As a result, one of the two electrodes of the flying capacitor C201 is grounded. One of the two electrodes of the flying capacitor C200, the other of the two electrodes of the flying capacitor C201, and one of the two electrodes of the flying capacitor C203 are connected to the node N1. The other of the two electrodes of the flying capacitor C200, one of the two electrodes of the flying capacitor C202, and the other of the two electrodes of the flying capacitor C203 are connected to the node N2. The other of the two electrodes of the flying capacitor C202 is connected to the node N3.

Repetition of the first phase and the second phase described above enables the flying capacitors C200 to C203 to complementarily perform charge and discharge. For example, the charge from the flying capacitors C200 and C202 to the smoothing capacitors C210, C211, and C212 is performed in one of the first phase and the second phase, and the charge from the flying capacitors C201 and C203 to the smoothing capacitors C210, C211, and C212 is performed in the other of the first phase and the second phase. In other words, since the smoothing capacitors C210, C211, and C212 are constantly charged from any of the flying capacitors C200, C201, C202, and C203, any of the nodes N1 to N3 is charged at high speed even if current flows at high speed from any of the nodes N1 to N3 to the supply modulators 31 and 32 to suppress variation in potential at the nodes N1 to N3.

The switched-capacitor circuit 20 operates in the above manner to keep substantially the equal voltage at both ends of each of the smoothing capacitors C210, C211, and C212. In some examples, V1 to V3 meeting (V3−V2):(V2−V1):(V1−VG)=1:1:1 are kept at the three nodes N1 to N3 labelled as V1 to V3. VG represents the ground potential. For example, when the adjustment voltage supplied from the pre-regulator circuit 10 is 2 V, the switched-capacitor circuit 20 is configured to generate (1V, 2V, 3V) as the multiple discrete voltages (V1, V2, and V3).

It is noted that (V3−V2):(V2−V1):(V1−VG) is not limited to 1:1:1 and may be designed to an arbitrary ratio (for example, 1:2:3, 3:2:1, or the like).

The configuration of the switched-capacitor circuit 20 illustrated in FIG. 3 is only an example and is not limited to this. Part of the switched-capacitor circuit 20 is not necessarily included in the tracker circuit 1. For example, the flying capacitors C200 to C203 and the smoothing capacitors C210 to C212 are not necessarily included in the tracker circuit 1.

### 1.5 Circuit Configuration of Supply Modulator 31

Next, an exemplary circuit configuration of the supply modulator 31 will be described with reference to FIG. 3. The supply modulator 31 includes input terminals T311 to T313, an output terminal T317, and switches S311 to S313.

The input terminals T311, T312, and T313 are terminals through which the multiple discrete voltages V1, V2, and V3 generated by the switched-capacitor circuit 20 are received, respectively. The input terminals T311, T312, and T313 are connected to the output terminals T201, T202, and T203, respectively, of the switched-capacitor circuit 20 outside the supply modulator 31 and are connected to the switches S311, S312, and S313, respectively, inside the supply modulator 31.

The output terminal T317 is a terminal through which at least one of the multiple discrete voltages V1, V2, and V3 is selectively supplied to the power amplifier 71. The output terminal T317 is connected to the output terminal 44 of the tracker circuit 1 outside the supply modulator 31 and is connected to the switches S311, S312, and S313 inside the supply modulator 31.

The switch S311 is connected between the input terminal T311 and the output terminal T317. The switch S312 is connected between the input terminal T312 and the output terminal T317. The switch S313 is connected between the input terminal T313 and the output terminal T317.

Opening and closing (turning-off and turning-on) of these switches S311, S312, and S313 are switched in accordance with the multiple control signals CS31 from the digital control circuit 62. In the present exemplary embodiment, the switches S311, S312, and S313 are controlled so as to be exclusively turned on. In other words, the switches S311, S312, and S313 are controlled so that only one of the switches S311, S312, and S313 is closed and the remaining switches of the switches S311, S312, and S313 are opened. As a result, the supply modulator 31 is configured to supply one voltage selected from the multiple discrete voltages (V1, V2, and V3) to the power amplifier 71.

The circuit configuration of the supply modulator 31 illustrated in FIG. 3 is only an example and is not limited to this. Particularly, it is sufficient for the switches S311, S312, and S313 to selectively connect at least one of the three input terminals T311, T312, and T313 to the output terminal T317. The switches S311, S312, and S313 may have any configuration and may be controlled in any manner. For example, two of the switches S311, S312, and S313 may be closed and the remaining one switch of the switches S311, S312, and S313 may be opened.

### 1.6 Circuit Configuration of Supply Modulator 32

Next, an exemplary circuit configuration of the supply modulator 32 will be described with reference to FIG. 3. The supply modulator 32 includes input terminals T321 to T323, an output terminal T327, and switches S321 to S323.

The input terminals T321, T322, and T323 are terminals through which the multiple discrete voltages V1, V2, and V3 generated by the switched-capacitor circuit 20 are received, respectively. The input terminals T321, T322, and T323 are connected to the output terminals T201, T202, and T203, respectively, of the switched-capacitor circuit 20 outside the supply modulator 32 and are connected to the switches S321, S322, and S323, respectively, inside the supply modulator 32.

The output terminal T327 is a terminal through which at least one of the multiple discrete voltages V1, V2, and V3 is selectively supplied to the power amplifier 72. The output terminal T327 is connected to the output terminal 45 of the tracker circuit 1 outside the supply modulator 32 and is connected to the switches S321, S322, and S323 inside the supply modulator 32.

The switch S321 is connected between the input terminal T321 and the output terminal T327. The switch S322 is connected between the input terminal T322 and the output terminal T327. The switch S323 is connected between the input terminal T323 and the output terminal T327.

Opening and closing (turning-off and turning-on) of these switches S321, S322, and S323 are switched in accordance with the multiple control signals CS32 from the digital control circuit 62. In the present exemplary embodiment, the switches S321, S322, and S323 are controlled so as to be exclusively turned on. In other words, the switches S321, S322, and S323 are controlled so that only one of the switches S321, S322, and S323 is closed and the remaining switches of the switches S321, S322, and S323 are opened. As a result, the supply modulator 32 is configured to supply one voltage selected from the multiple discrete voltages (V1, V2, and V3) to the power amplifier 72.

The circuit configuration of the supply modulator 32 illustrated in FIG. 3 is only an example and is not limited to this. Particularly, it is sufficient for the switches S321, S322, and S323 to selectively connect at least one of the three input terminals T321, T322, and T323 to the output terminal T327. The switches S321, S322, and S323 may have any configuration and may be controlled in any manner. For example, two of the switches S321, S322, and S323 may be closed and the remaining one switch of the switches S321, S322, and S323 may be opened.

### 1.7 Circuit Configuration of Digital Control Circuit 62

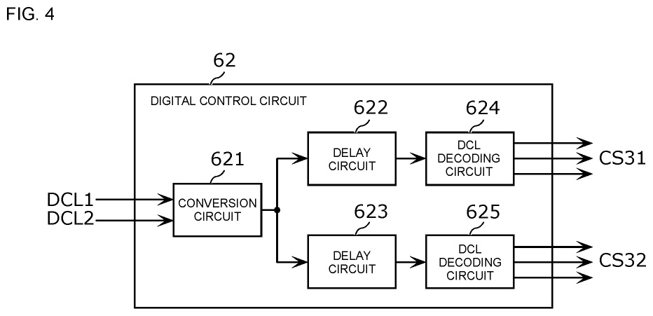

An exemplary circuit configuration of the digital control circuit 62 will now be described with reference to FIG. 4. FIG. 4 is a diagram illustrating the circuit configuration of the digital control circuit 62 according to the present exemplary embodiment.

FIG. 4 illustrates an exemplary circuit configuration and the digital control circuit 62 may be mounted using any of a variety of circuit implementation and various circuit techniques. Accordingly, the description of the digital control circuit 62 provided below should not be limitedly interpreted.

The digital control circuit 62 includes a conversion circuit 621, delay circuits 622 and 623, and DCL decoding circuits 624 and 625.

The conversion circuit 621 is connected to the multiple control input terminals 43 of the tracker circuit 1 outside the digital control circuit 62 and is connected to the delay circuits 622 and 623 inside the digital control circuit 62. The conversion circuit 621 is configured to convert the multiple DCL signals (for example, DCL1 and DCL2) acquired through the multiple control input terminals 43 into a multibit digital signal (for example, a two-bit digital signal) to output the generated multi-bit digital signal to the delay circuits 622 and 623.

The delay circuit 622 is an example of a first delay circuit and is connected between the multiple control input terminals 43 of the tracker circuit 1 and the supply modulator 31. In some examples, the delay circuit 622 is connected between the conversion circuit 621 and the DCL decoding circuit 624. The delay circuit 622 is configured to delay the multi-bit digital signal supplied from the conversion circuit 621 to output the multi-bit digital signal to the DCL decoding circuit 624. In other words, the delay circuit 622 is configured to control the amount of delay of the multiple control signals CS31. The delay circuit 622 is composed of, for example, a flip-flop circuit or an RC circuit.

The delay circuit 623 is an example of a second delay circuit and is connected between the multiple control input terminals 43 of the tracker circuit 1 and the supply modulator 32. In some examples, the delay circuit 623 is connected between the conversion circuit 621 and the DCL decoding circuit 625. The delay circuit 623 is configured to delay the multi-bit digital signal supplied from the conversion circuit 621 to output the multi-bit digital signal to the DCL decoding circuit 625. In other words, the delay circuit 623 is configured to control the amount of delay of the multiple control signals CS32. The delay circuit 623 is composed of, for example, a flip-flop circuit or an RC circuit.

The DCL decoding circuit 624 is an example of a first decoding circuit and is connected between the delay circuit 622 and the supply modulator 31. The DCL decoding circuit 624 is configured to decode the multi-bit digital signal received from the conversion circuit 621 via the delay circuit 622 to generate the multiple control signals CS31. The multiple control signals CS31 are supplied to the supply modulator 31.

The DCL decoding circuit 625 is an example of a second decoding circuit and is connected between the delay circuit 623 and the supply modulator 32. The DCL decoding circuit 625 is configured to decode the multi-bit digital signal received from the conversion circuit 621 via the delay circuit 623 to generate the multiple control signals CS32. The multiple control signals CS32 are supplied to the supply modulator 32.

The circuit configuration of the digital control circuit 62 illustrated in FIG. 4 is only an example and is not limited to this. For example, the digital control circuit 62 does not necessarily include the conversion circuit 621 and/or the delay circuit 623. For example, the delay circuit 622 may be connected between the DCL decoding circuit 624 and the supply modulator 31 and the delay circuit 623 may be connected between the DCL decoding circuit 625 and the supply modulator 32.

### 1.8 Outline

As described above, the tracker circuit 1 according to the present exemplary embodiment includes the multiple control input terminals 43 through which the respective multiple DCL signals are received, at least one switch included in the switched-capacitor circuit 20 configured to generate the multiple discrete voltages from input voltage, the supply modulator 31 configured to selectively output at least one of the multiple discrete voltages to the power amplifier 71 based on the multiple DCL signals, the supply modulator 32 configured to selectively output at least one of the multiple discrete voltages to the power amplifier 72 based on the multiple DCL signals, and the delay circuit 622 connected between the multiple control input terminals 43 and the supply modulator 31.

With the above configuration, the delay circuit 622 is connected between the multiple control input terminals 43 through which the respective multiple DCL signals are received and the supply modulator 31 that supplies the voltage to the power amplifier 71. Accordingly, when delay from the radio frequency signal of the voltage to be supplied to the power amplifier 72 is greater than delay from the radio frequency signal of the voltage to be supplied to the power amplifier 71, delaying the multiple control signals CS31 for controlling the supply modulator 31 that supplies the voltage to the power amplifier 71 by the delay circuit 622 enables the delays of the power supply voltage in the power amplifiers 71 and 72 to be equalized. As a result, the trackability of the power supply voltage to the envelope of the radio frequency signal in both of the power amplifiers 71 and 72 is improved and the power efficiency in the D-ET mode is improved. In particular, since the delay circuit 622 is provided not on a power supply voltage line through which the voltage is supplied from the supply modulator 31 to the power amplifier 71 but on a control signal line through which the control signals are transmitted, loss on the power supply voltage line can be suppressed to produce great improvement of the power efficiency.

For example, in the tracker circuit 1 according to the present exemplary embodiment, the delay circuit 622 may be a flip-flop circuit.

With the above configuration, the delay circuit 622 can be realized with a simple circuit configuration.

For example, in the tracker circuit 1 according to the present exemplary embodiment, the delay circuit 622 may be an RC circuit.

With the above configuration, the delay circuit 622 can be realized with a simple circuit configuration.

For example, the tracker circuit 1 according to the present exemplary embodiment may further include the digital control circuit 62 configured to generate the multiple control signals CS31 for controlling the supply modulator 31 and the multiple control signals CS32 for controlling the supply modulator 32 based on the multiple DCL signals. The delay circuit 622 may be included in the digital control circuit 62.

With the above configuration, the digital control circuit 62 including the delay circuit 622 is included in the same tracker circuit 1 as the tracker circuit 1 including the supply modulators 31 and 32. Accordingly, the switching timing of the supply modulators 31 and 32 can be controlled with more accuracy. As a result, the trackability of the power supply voltage to the envelope of the radio frequency signal in both of the power amplifiers 71 and 72 can be improved and the power efficiency in the D-ET mode can be improved.

For example, in the tracker circuit 1 according to the present exemplary embodiment, the digital control circuit 62 may further include the conversion circuit 621 configured to convert the multiple DCL signals into the multi-bit digital signal, the DCL decoding circuit 624 configured to generate the multiple control signals CS31 based on the multi-bit digital signal, and the DCL decoding circuit 625 configured to generate the multiple control signals CS32 based on the multi-bit digital signal. The delay circuit 622 may be connected between the conversion circuit 621 and the DCL decoding circuit 624.

With the above configuration, the delay circuit 622 is connected between the conversion circuit 621 and the DCL decoding circuit 624. Accordingly, it is sufficient for the delay circuit 622 to be configured to delay one multi-bit digital signal, thus simplifying the circuit configuration of the delay circuit 622, compared with a case in which the multiple control signals CS31 are delayed.

For example, the tracker circuit 1 according to the present exemplary embodiment may further include the delay circuit 623 connected between the multiple control input terminals 43 and the supply modulator 32.

With the above configuration, the delay circuit 623 is connected between the multiple control input terminals 43 through which the respective multiple DCL signals are received and the supply modulator 32 that supplies the voltage to the power amplifier 72. Accordingly, not only when delay from the radio frequency signal of the voltage to be supplied to the power amplifier 72 is greater than delay from the radio frequency signal of the voltage to be supplied to the power amplifier 71 but also when delay from the radio frequency signal of the voltage to be supplied to the power amplifier 71 is greater than delay from the radio frequency signal of the voltage to be supplied to the power amplifier 72, the power efficiency in the D-ET mode can be improved.

For example, in the tracker circuit 1 according to the present exemplary embodiment, the delay circuit 623 may be a flip-flop circuit.

With the above configuration, the delay circuit 623 can be realized with a simple circuit configuration.

For example, in the tracker circuit 1 according to the present exemplary embodiment, the delay circuit 623 may be an RC circuit.

With the above configuration, the delay circuit 623 can be realized with a simple circuit configuration.

For example, the tracker circuit 1 according to the present exemplary embodiment may further include the digital control circuit 62 configured to generate the multiple control signals CS31 for controlling the supply modulator 31 and the multiple control signals CS32 for controlling the supply modulator 32 based on the multiple DCL signals. The delay circuits 622 and 623 may be included in the digital control circuit 62.

With the above configuration, the digital control circuit 62 including the delay circuits 622 and 623 is included in the same tracker circuit 1 as the tracker circuit 1 including the supply modulators 31 and 32. Accordingly, the switching timing of the supply modulators 31 and 32 can be controlled with more accuracy. As a result, the trackability of the power supply voltage to the envelope of the radio frequency signal in both of the power amplifiers 71 and 72 can be improved and the power efficiency in the D-ET mode can be improved.

For example, in the tracker circuit 1 according to the present exemplary embodiment, the digital control circuit 62 may further include the conversion circuit 621 configured to convert the multiple DCL signals into the multi-bit digital signal, the DCL decoding circuit 624 configured to generate the multiple control signals CS31 based on the multi-bit digital signal, and the DCL decoding circuit 625 configured to generate the multiple control signals CS32 based on the multi-bit digital signal. The delay circuit 622 may be connected between the conversion circuit 621 and the DCL decoding circuit 624. The delay circuit 623 may be connected between the conversion circuit 621 and the DCL decoding circuit 625.

With the above configuration, the delay circuit 622 is connected between the conversion circuit 621 and the DCL decoding circuit 624 and the delay circuit 623 is connected between the conversion circuit 621 and the DCL decoding circuit 625. Accordingly, it is sufficient for each of the delay circuits 622 and 623 to be configured to delay one multi-bit digital signal, thus simplifying the circuit configuration of each of the delay circuits 622 and 623, compared with a case in which the multiple control signals CS31 and CS32 are delayed.

### Modification of First Exemplary Embodiment

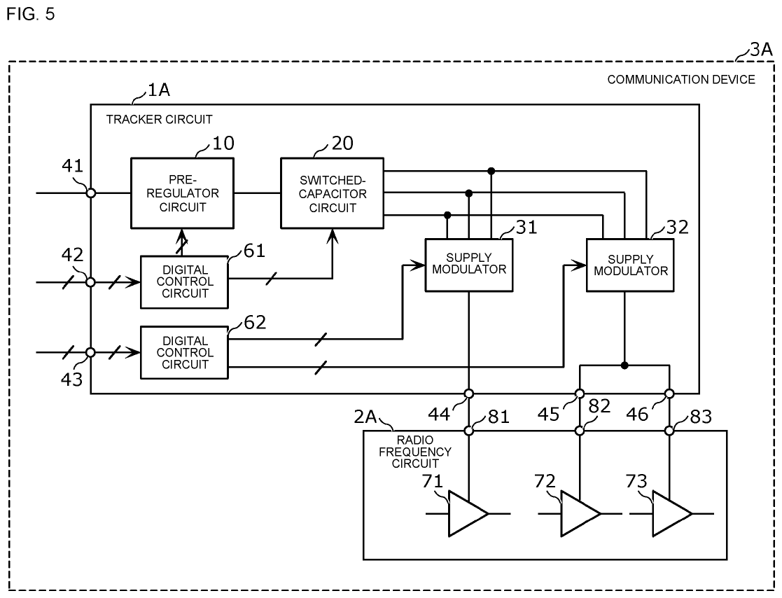

Next, a modification of the first exemplary embodiment will be described. The present modification mainly differs from the first exemplary embodiment described above in that the supply modulator 32 is connected to multiple power amplifiers. The present modification will be described with reference to FIG. 5, focusing on points different from the first exemplary embodiment.

### 1.9 Circuit Configuration

FIG. 5 is a diagram illustrating the circuit configuration of a communication device 3A according to the present modification. FIG. 5 illustrates an exemplary circuit configuration and the communication device 3A may be mounted using any of a variety of circuit implementation and various circuit techniques. Accordingly, the description of the communication device 3A provided below should not be limitedly interpreted.

The communication device 3A is usable for the provision of the wireless connection, as in the first exemplary embodiment. As illustrated in FIG. 5, the communication device 3A includes a tracker circuit 1A and a radio frequency circuit 2A.

The tracker circuit 1A is configured to concurrently supply the power supply voltage to the power amplifiers 71 and 72 and a power amplifier 73 in the D-ET mode. The tracker circuit 1A may supply the power supply voltage to the power amplifiers 71, 72, and 73 in the APT mode. The tracker circuit 1A is configured to be mounted on one semiconductor integrated circuit and may be called the PMIC.

In some examples, the tracker circuit 1A includes the pre-regulator circuit 10, the switched-capacitor circuit 20, the supply modulators 31 and 32, the input terminal 41, the multiple control input terminals 42 and 43, the output terminals 44 and 45 and an output terminal 46, and the digital control circuits 61 and 62.

The output terminal 46 is an external connection terminal through which the power supply voltage is supplied to the power amplifier 73. The output terminal 46 is connected to a power supply voltage terminal 83 of the radio frequency circuit 2A outside the tracker circuit 1A and is connected to the supply modulator 32 inside the tracker circuit 1A.

The radio frequency circuit 2A is configured to up-convert an IF signal or a baseband signal, which is received from the outside of the radio frequency circuit 2A, to generate two radio frequency signals in a certain band. In addition, the radio frequency circuit 2A is configured to amplify the generated two radio frequency signals to output the amplified radio frequency signals to one or more antennas. The radio frequency circuit 2A is configured to be mounted on one semiconductor integrated circuit and may be called the RFIC.

In some examples, the radio frequency circuit 2A includes the power amplifiers 71, 72, and 73 and the power supply voltage terminals 81, 82, and 83.

The power supply voltage terminal 83 is an external connection terminal through which the power supply voltage used in the power amplifier 73 is received from the tracker circuit 1A. The power supply voltage terminal 83 is connected to the output terminal 46 of the tracker circuit 1A outside the radio frequency circuit 2A and is connected to the power amplifier 73 inside the radio frequency circuit 2A.

The power amplifier 73 is configured to amplify the radio frequency signal in the certain band using the power supply voltage supplied from the supply modulator 32 via the output terminal 46 and the power supply voltage terminal 83.

Although the power supply voltage is supplied from the supply modulator 32 to the multiple power amplifiers (the power amplifiers 72 and 73) in FIG. 5, the power supply voltage may be supplied from the supply modulator 31 to multiple power amplifiers.

### 1.10 Outline

As described above, in the tracker circuit 1A according to the present exemplary embodiment, the supply modulator 32 is configured to selectively output at least one of the multiple discrete voltages to the power amplifiers 72 and 73 based on the multiple DCL signals.

With the above configuration, the tracker circuit 1A is configured to supply the voltage to the power amplifiers 71, 72, and 73 of a larger number than the number of the power amplifiers in the first exemplary embodiment.

### Second Exemplary Embodiment

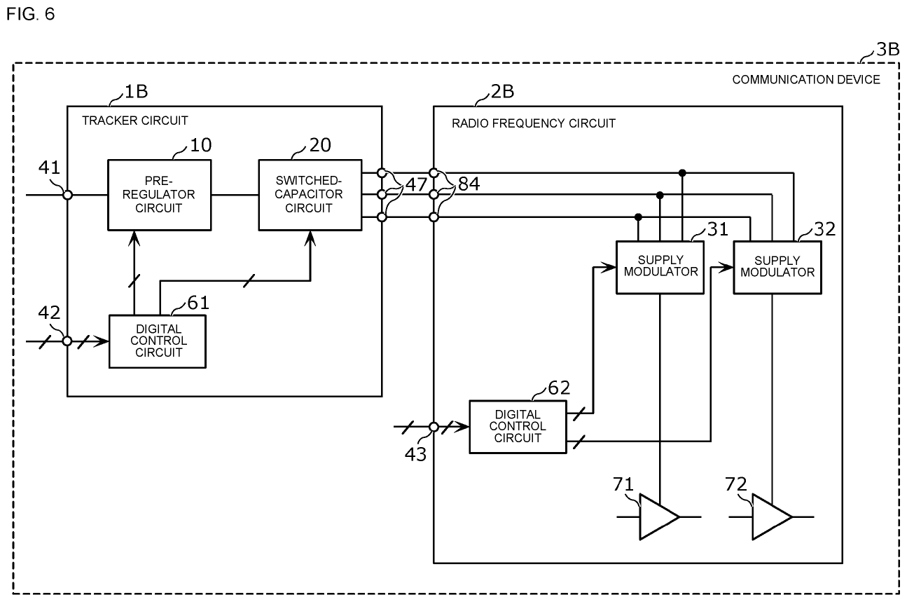

Next, a second exemplary embodiment will be described. The present exemplary embodiment mainly differs from the first exemplary embodiment described above in that the supply modulators 31 and 32 and the digital control circuit 62 are included not in the tracker circuit but in the radio frequency circuit. The present exemplary embodiment will be described with reference to FIG. 6, focusing on points different from the first exemplary embodiment.

### 2.1 Circuit Configuration

FIG. 6 is a diagram illustrating the circuit configuration of a communication device 3B according to the present exemplary embodiment. FIG. 6 illustrates an exemplary circuit configuration and the communication device 3B may be mounted using any of a variety of circuit implementation and various circuit techniques. Accordingly, the description of the communication device 3B provided below should not be limitedly interpreted.

The communication device 3B is usable for the provision of the wireless connection, as in the first exemplary embodiment. As illustrated in FIG. 6, the communication device 3B includes a tracker circuit 1B and a radio frequency circuit 2B.

The tracker circuit 1B is configured to concurrently supply the power supply voltage to the power amplifiers 71 and 72 in the D-ET mode. The tracker circuit 1B may supply the power supply voltage to the power amplifiers 71 and 72 in the APT mode. The tracker circuit 1B is configured to be mounted on one semiconductor integrated circuit and may be called the PMIC.

In some examples, the tracker circuit 1B includes the pre-regulator circuit 10, the switched-capacitor circuit 20, the input terminal 41, the multiple control input terminals 42, multiple output terminals 47, and the digital control circuit 61.

The multiple output terminals 47 are multiple external connection terminals through which the respective multiple discrete voltages are supplied to the radio frequency circuit 2B. The multiple output terminals 47 are connected to multiple discrete voltage terminals 84 of the radio frequency circuit 2B outside the tracker circuit 1B and are connected to the switched-capacitor circuit 20 inside the tracker circuit 1B.

The radio frequency circuit 2B is an example of a radio frequency circuit and includes the supply modulators 31 and 32, the multiple control input terminals 43 (examples of second external connection terminals), the digital control circuit 62, the power amplifiers 71 and 72, and the multiple discrete voltage terminals 84. The radio frequency circuit 2B is configured to be mounted on one semiconductor integrated circuit and may be called the RFIC.

The multiple discrete voltage terminals 84 are examples of multiple first external connection terminals and are multiple external connection terminals through which the respective multiple discrete voltages are received from the tracker circuit 1B. The multiple discrete voltage terminals 84 are connected to the multiple output terminals 47 of the tracker circuit 1B outside the radio frequency circuit 2B and are connected to the supply modulators 31 and 32 inside the radio frequency circuit 2B.

### 2.2 Outline

As described above, the radio frequency circuit 2B according to the present exemplary embodiment includes the multiple discrete voltage terminals 84 through which the respective multiple discrete voltages are received, the multiple control input terminals 43 through which the respective multiple DCL signals are received, the power amplifiers 71 and 72, the supply modulator 31 configured to selectively output at least one of the multiple discrete voltages to the power amplifier 71 based on the multiple DCL signals, the supply modulator 32 configured to selectively output at least one of the multiple discrete voltages to the power amplifier 72 based on the multiple DCL signals, and the delay circuit 622 connected between the multiple control input terminals 43 and the supply modulator 31.

With the above configuration, the delay circuit 622 is connected between the multiple control input terminals 43 through which the respective multiple DCL signals are received and the supply modulator 31 that supplies the voltage to the power amplifier 71. Accordingly, when delay from the radio frequency signal of the voltage to be supplied to the power amplifier 72 is greater than delay from the radio frequency signal of the voltage to be supplied to the power amplifier 71, delaying the multiple control signals CS31 for controlling the supply modulator 31 that supplies the voltage to the power amplifier 71 by the delay circuit 622 enables the delays of the power supply voltage in the power amplifiers 71 and 72 to be equalized. As a result, the trackability of the power supply voltage to the envelope of the radio frequency signal in both of the power amplifiers 71 and 72 can be improved and the power efficiency in the D-ET mode can be improved. In particular, since the delay circuit 622 is provided not on the power supply voltage line through which the voltage is supplied from the supply modulator 31 to the power amplifier 71 but on the control signal line through which the control signals are transmitted, the loss on the power supply voltage line can be suppressed to produce great improvement of the power efficiency.

For example, in the radio frequency circuit 2B according to the present exemplary embodiment, the delay circuit 622 may be a flip-flop circuit.

With the above configuration, the delay circuit 622 can be realized with a simple circuit configuration.

For example, in the radio frequency circuit 2B according to the present exemplary embodiment, the delay circuit 622 may be an RC circuit.

With the above configuration, the delay circuit 622 can be realized with a simple circuit configuration.

For example, the radio frequency circuit 2B according to the present exemplary embodiment may further include the digital control circuit 62 configured to generate the multiple control signals CS31 for controlling the supply modulator 31 and the multiple control signals CS32 for controlling the supply modulator 32 based on the multiple DCL signals. The delay circuit 622 may be included in the digital control circuit 62.

With the above configuration, the digital control circuit 62 including the delay circuit 622 is included in the same radio frequency circuit 2B as the radio frequency circuit 2B including the supply modulators 31 and 32. Accordingly, the switching timing of the supply modulators 31 and 32 can be controlled with more accuracy. As a result, the trackability of the power supply voltage to the envelope of the radio frequency signal in both of the power amplifiers 71 and 72 can be improved and the power efficiency in the D-ET mode can be improved.

For example, in the radio frequency circuit 2B according to the present exemplary embodiment, the digital control circuit 62 may further include the conversion circuit 621 configured to convert the multiple DCL signals into the multi-bit digital signal, the DCL decoding circuit 624 configured to generate the multiple control signals CS31 based on the multi-bit digital signal, and the DCL decoding circuit 625 configured to generate the multiple control signals CS32 based on the multi-bit digital signal. The delay circuit 622 may be connected between the conversion circuit 621 and the DCL decoding circuit 624.

With the above configuration, the delay circuit 622 is connected between the conversion circuit 621 and the DCL decoding circuit 624. Accordingly, it is sufficient for the delay circuit 622 to be configured to delay one multi-bit digital signal, thus simplifying the circuit configuration of the delay circuit 622, compared with the case in which the multiple control signals CS31 are delayed.

For example, the radio frequency circuit 2B according to the present exemplary embodiment may further include the delay circuit 623 connected between the multiple control input terminals 43 and the supply modulator 32.

With the above configuration, the delay circuit 623 is connected between the multiple control input terminals 43 through which the respective multiple DCL signals are received and the supply modulator 32 that supplies the voltage to the power amplifier 72. Accordingly, not only when delay from the radio frequency signal of the voltage to be supplied to the power amplifier 72 is greater than delay from the radio frequency signal of the voltage to be supplied to the power amplifier 71 but also when delay from the radio frequency signal of the voltage to be supplied to the power amplifier 71 is greater than delay from the radio frequency signal of the voltage to be supplied to the power amplifier 72, the power efficiency in the D-ET mode can be improved.

For example, in the radio frequency circuit 2B according to the present exemplary embodiment, the delay circuit 623 may be a flip-flop circuit.

With the above configuration, the delay circuit 623 can be realized with a simple circuit configuration.

For example, in the radio frequency circuit 2B according to the present exemplary embodiment, the delay circuit 623 may be an RC circuit.

With the above configuration, the delay circuit 623 can be realized with a simple circuit configuration.

For example, the radio frequency circuit 2B according to the present exemplary embodiment may further include the digital control circuit 62 configured to generate the multiple control signals CS31 for controlling the supply modulator 31 and the multiple control signals CS32 for controlling the supply modulator 32 based on the multiple DCL signals. The delay circuits 622 and 623 may be included in the digital control circuit 62.

With the above configuration, the digital control circuit 62 including the delay circuits 622 and 623 is included in the same radio frequency circuit 2B as the radio frequency circuit 2B including the supply modulators 31 and 32. Accordingly, the switching timing of the supply modulators 31 and 32 can be controlled with more accuracy. As a result, the trackability of the power supply voltage to the envelope of the radio frequency signal in both of the power amplifiers 71 and 72 can be improved and the power efficiency in the D-ET mode can be improved.

For example, in the radio frequency circuit 2B according to the present exemplary embodiment, the digital control circuit 62 may further include the conversion circuit 621 configured to convert the multiple DCL signals into the multi-bit digital signal, the DCL decoding circuit 624 configured to generate the multiple control signals CS31 based on the multi-bit digital signal, and the DCL decoding circuit 625 configured to generate the multiple control signals CS32 based on the multi-bit digital signal. The delay circuit 622 may be connected between the conversion circuit 621 and the DCL decoding circuit 624. The delay circuit 623 may be connected between the conversion circuit 621 and the DCL decoding circuit 625.

With the above configuration, the delay circuit 622 is connected between the conversion circuit 621 and the DCL decoding circuit 624 and the delay circuit 623 is connected between the conversion circuit 621 and the DCL decoding circuit 625. Accordingly, it is sufficient for each of the delay circuits 622 and 623 to be configured to delay one multi-bit digital signal, thus simplifying the circuit configuration of each of the delay circuits 622 and 623, compared with the case in which the multiple control signals CS31 and CS32 are delayed.

### Third Exemplary Embodiment

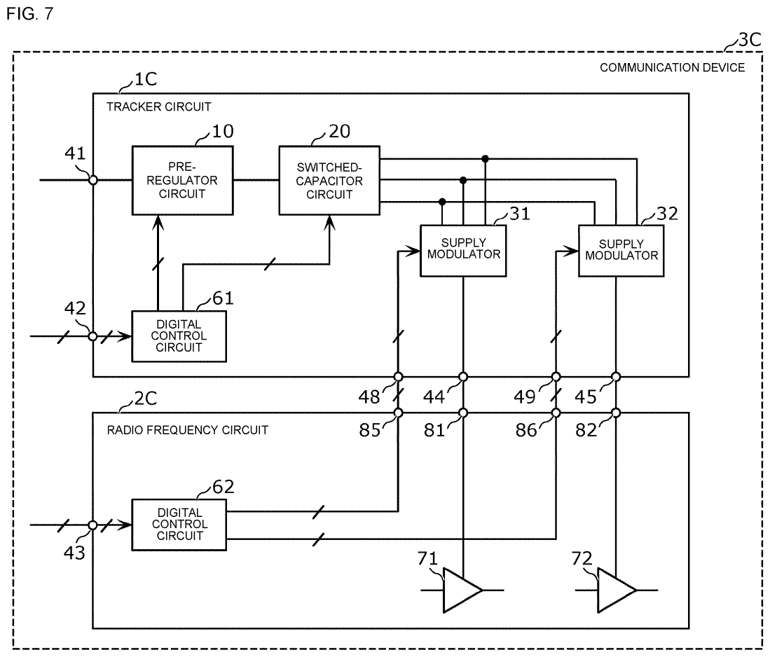

Next, a third exemplary embodiment will be described. The present exemplary embodiment mainly differs from the first exemplary embodiment described above in that the digital control circuit 62 is included not in the tracker circuit but in the radio frequency circuit. The present exemplary embodiment will be described with reference to FIG. 7, focusing on points different from the first exemplary embodiment.

### 3.1 Circuit Configuration

FIG. 7 is a diagram illustrating the circuit configuration of a communication device 3C according to the present exemplary embodiment. FIG. 7 illustrates an exemplary circuit configuration and the communication device 3C may be mounted using any of a variety of circuit implementation and various circuit techniques. Accordingly, the description of the communication device 3C provided below should not be limitedly interpreted.

The communication device 3C is usable for the provision of the wireless connection, as in the first exemplary embodiment. As illustrated in FIG. 7, the communication device 3C includes a tracker circuit 1C and a radio frequency circuit 2C.

The tracker circuit 1C is configured to concurrently supply the power supply voltage to the power amplifiers 71 and 72 in the D-ET mode. The tracker circuit 1C may supply the power supply voltage to the power amplifiers 71 and 72 in the APT mode. The tracker circuit 1C is configured to be mounted on one semiconductor integrated circuit and may be called the PMIC.

In some examples, the tracker circuit 1C includes the pre-regulator circuit 10, the switched-capacitor circuit 20, the supply modulators 31 and 32, the input terminal 41, the multiple control input terminals 42, multiple control input terminals 48 and 49, the output terminals 44 and 45, and the digital control circuit 61.

The multiple control input terminals 48 are multiple external connection terminals through which the respective multiple control signals CS31 for controlling the supply modulator 31 are received from the radio frequency circuit 2C. The multiple control input terminals 48 are connected to multiple control output terminals 85 of the radio frequency circuit 2C outside the tracker circuit 1C and are connected to the supply modulator 31 inside the tracker circuit 1C.

The multiple control input terminals 49 are multiple external connection terminals through which the respective multiple control signals CS32 for controlling the supply modulator 32 are received from the radio frequency circuit 2C. The multiple control input terminals 49 are connected to multiple control output terminals 86 of the radio frequency circuit 2C outside the tracker circuit 1C and are connected to the supply modulator 32 inside the tracker circuit 1C.

The radio frequency circuit 2C is configured to up-convert an IF signal or a baseband signal, which is received from the outside of the radio frequency circuit 2C, to generate two radio frequency signals in a certain band. In addition, the radio frequency circuit 2C is configured to amplify the generated two radio frequency signals to output the amplified radio frequency signals to one or more antennas. The radio frequency circuit 2C is configured to be mounted on one semiconductor integrated circuit and may be called the RFIC.

In some examples, the radio frequency circuit 2C includes the multiple control input terminals 43, the digital control circuit 62, the power amplifiers 71 and 72, the power supply voltage terminals 81 and 82, and the multiple control output terminals 85 and 86.

The multiple control output terminals 85 are multiple external connection terminals through which the respective multiple control signals CS31 are supplied to the tracker circuit 1C. The multiple control output terminals 85 are connected to the multiple control input terminals 48 of the tracker circuit 1C outside the radio frequency circuit 2C and are connected to the digital control circuit 62 inside the radio frequency circuit 2C.

The multiple control output terminals 86 are multiple external connection terminals through which the respective multiple control signals CS32 are supplied to the tracker circuit 1C. The multiple control output terminals 86 are connected to the multiple control input terminals 49 of the tracker circuit 1C outside the radio frequency circuit 2C and are connected to the digital control circuit 62 inside the radio frequency circuit 2C.

### 3.2 Outline

As described above, the radio frequency circuit 2C according to the present exemplary embodiment includes the multiple control input terminals 43 through which the respective multiple DCL signals are received, the power amplifiers 71 and 72, the multiple control output terminals 85 through which the multiple control signals CS31 are supplied to the supply modulator 31 configured to selectively output at least one of the multiple discrete voltages to the power amplifier 71 based on the multiple DCL signals, the multiple control output terminals 86 through which the multiple control signals CS32 are supplied to the supply modulator 32 configured to selectively output at least one of the multiple discrete voltages to the power amplifier 72 based on the multiple DCL signals, and the delay circuit 622 connected between the multiple control input terminals 43 and the multiple control output terminals 85.

With the above configuration, even if the supply modulators 31 and 32 are not included in the radio frequency circuit 2C, the same technical effects as those of the radio frequency circuit 2B according to the second exemplary embodiment can be achieved.

### Other Embodiments

Although the tracker circuits and the radio frequency circuits according to the present disclosure are described above based on the exemplary embodiments, the tracker circuits and the radio frequency circuits according to the present disclosure are not limited to the above exemplary embodiments. Other embodiments realized by combining arbitrary components in the above exemplary embodiments, modifications resulting from making various modifications supposed by the person skilled in the art to the above exemplary embodiments without departing from the spirit and scope of the present disclosure, and various devices incorporating the tracker circuits and/or the radio frequency circuits described above are also included in the present disclosure.

For example, in the circuit configurations of the various circuits according to the respective exemplary embodiments described above, other circuit elements, wiring lines, and so on may be provided between the paths with which the respective circuit elements are connected to the signal paths, which are disclosed in the drawings. For example, an inductor and/or a capacitor may be provided between the tracker circuit and the power amplifier.

For example, the modification of the first exemplary embodiment described above may be applied to the second and third exemplary embodiments described above.

Although the number of the multiple discrete voltages which the switched-capacitor circuit 20 is configured to generate is three in the respective exemplary embodiments described above, the number of the multiple discrete voltages is not limited to this. For example, the switched-capacitor circuit 20 may generate two, four, five, six, or seven or more discrete voltages. In this case, the number of the switches included in the supply modulator may be increased or decreased depending on the number of the multiple discrete voltages.

Features of the tracker circuits and the radio-frequency circuits described based on the respective exemplary embodiments described above will be described.

The exemplary aspects of the present disclosure can be widely usable for a communication device, such as a mobile phone, as the tracker circuit that supplies the power supply voltage to the power amplifier and/or the radio frequency circuit that amplifies the radio frequency signal.

### REFERENCE SIGNS LIST

1, 1A, 1B, 1C tracker circuit
2, 2A, 2B, 2C radio frequency circuit
3, 3A, 3B, 3C communication device
10 pre-regulator circuit
20 switched-capacitor circuit
31, 32 supply modulator
41, T101, T200, T311, T312, T313, T321, T322, T323 input terminal
42, 43, 48, 49 control input terminal
44, 45, 46, 47, T102, T201, T202, T203, T317, T327 output terminal
61, 62 digital control circuit
71, 72, 73 power amplifier
621 conversion circuit
622, 623 delay circuit
624, 625 DCL decoding circuit
C101 capacitor
C200, C201, C202, C203 flying capacitor
C210, C211, C212 smoothing capacitor
CS10, CS20, CS31, CS32 control signal
L101 power inductor
S101, S102, S103, S104, S200, S201, S202, S203, S204, S205, S206, S207, S208, S209, S210, S211, S311, S312, S313, S321, S322, S323 switch

1. A tracker circuit, comprising:
a plurality of external connection terminals configured to receive a plurality of digital control level signals, each of the plurality of external connection terminals receiving a respective digital control level signal of the plurality of digital control level signals;
a switched-capacitor circuit configured to generate a plurality of discrete voltages from an input voltage, the switched-capacitor circuit comprising at least a switch;
a first supply modulator configured to selectively output at least one of the plurality of discrete voltages as a first power supply to a first power amplifier based on the plurality of digital control level signals with a first delay;
a second supply modulator configured to selectively output at least one of the plurality of discrete voltages as a second power supply to a second power amplifier based on the plurality of digital control level signals; and
a first delay circuit configured to generate the first delay.

2. The tracker circuit according to claim 1, wherein the first delay circuit includes a flip-flop circuit.

3. The tracker circuit according to claim 1, wherein the first delay circuit includes an RC circuit.

4. The tracker circuit according to claim 1, further comprising:
a digital control circuit configured to generate a plurality of first control signals for controlling the first supply modulator and a plurality of second control signals for controlling the second supply modulator based on the plurality of digital control level signals,
wherein the first delay circuit is included in the digital control circuit.

5. The tracker circuit according to claim 4, wherein:
the digital control circuit further includes:
a conversion circuit configured to convert the plurality of digital control level signals into a multi-bit digital signal,
a first decoding circuit configured to generate the plurality of first control signals based on the multi-bit digital signal with the first delay, and
a second decoding circuit configured to generate the plurality of second control signals based on the multi-bit digital signal; and
the first delay circuit is configured to:
apply the first delay to the multi-bit digital signal to generate a first delayed multi-bit digital signal, and
provide the first delayed multi-bit digital signal to the first decoding circuit.

6. The tracker circuit according to claim 1, further comprising:
a second delay circuit configured to generate a second delay,
wherein the second supply modulator is configured to provide the second power supply to the second power amplifier based on the plurality of digital control level signals with the second delay.

7. The tracker circuit according to claim 6, wherein the second delay circuit includes a flip-flop circuit.

8. The tracker circuit according to claim 6, wherein the second delay circuit includes an RC circuit.

9. The tracker circuit according to claim 6, further comprising:
a digital control circuit configured to generate a plurality of first control signals for controlling the first supply modulator and a plurality of second control signals for controlling the second supply modulator based on the plurality of digital control level signals,
wherein the first delay circuit and the second delay circuit are included in the digital control circuit.

10. The tracker circuit according to claim 9, wherein:
the digital control circuit further includes:
a conversion circuit configured to convert the plurality of digital control level signals into a multi-bit digital signal,
a first decoding circuit configured to generate the plurality of first control signals based on a first delayed multi-bit digital signal with the first delay to the multi-bit digital signal, and
a second decoding circuit configured to generate the plurality of second control signals based on a second delayed multi-bit digital signal;
the first delay circuit is configured to generate the first delayed multi-bit digital signal with the first delay to the multi-bit digital signal; and
the second delay circuit is configured to generate the second delayed multi-bit digital signal with the second delay to the multi-bit digital signal.

11. A radio-frequency circuit, comprising:
a plurality of first external connection terminals configured to receive a plurality of discrete voltages, each of the plurality of first external connection terminals receiving a respective discrete voltage of the plurality of discrete voltages;
a plurality of second external connection terminals configured to receive a plurality of digital control level signals, each of the plurality of second external connection terminals receiving a respective digital control level signal of the plurality of digital control level signals;
a first power amplifier and a second power amplifier;
a first supply modulator configured to selectively output at least one of the plurality of discrete voltages as a first power supply to the first power amplifier based on the plurality of digital control level signals with a first delay;
a second supply modulator configured to selectively output at least one of the plurality of discrete voltages as a second power supply to the second power amplifier based on the plurality of digital control level signals; and
a first delay circuit configured to generate the first delay.

12. The radio-frequency circuit according to claim 11, wherein the first delay circuit includes a flip-flop circuit.

13. The radio-frequency circuit according to claim 11, wherein the first delay circuit includes an RC circuit.

14. The radio-frequency circuit according to claim 11, further comprising:
a digital control circuit configured to generate a plurality of first control signals for controlling the first supply modulator and a plurality of second control signals for controlling the second supply modulator based on the plurality of digital control level signals,
wherein the first delay circuit is included in the digital control circuit.

15. The radio-frequency circuit according to claim 14, wherein:
the digital control circuit further includes:
a conversion circuit configured to convert the plurality of digital control level signals into a multi-bit digital signal,
a first decoding circuit configured to generate the plurality of first control signals based on the multi-bit digital signal with the first delay, and
a second decoding circuit configured to generate the plurality of second control signals based on the multi-bit digital signal; and
the first delay circuit is configured to:
apply the first delay to the multi-bit digital signal to generate a first delayed multi-bit digital signal, and provide the first delayed multi-bit digital signal to the first decoding circuit.

16. The radio-frequency circuit according to claim 11, further comprising:
a second delay circuit configured to generate a second delay,
wherein the second supply modulator is configured to provide the second power supply to the second power amplifier based on the plurality of digital control level signals with the second delay.

17. The radio-frequency circuit according to claim 16, wherein the second delay circuit includes a flip-flop circuit.

18. The radio-frequency circuit according to claim 16, wherein the second delay circuit includes an RC circuit.

19. The radio-frequency circuit according to claim 16, further comprising:
a digital control circuit configured to generate a plurality of first control signals for controlling the first supply modulator and a plurality of second control signals for controlling the second supply modulator based on the plurality of digital control level signals,
wherein the first delay circuit and the second delay circuit are included in the digital control circuit.

20. The radio-frequency circuit according to claim 19, wherein:
the digital control circuit further includes:
a conversion circuit configured to convert the plurality of digital control level signals into a multi-bit digital signal,
a first decoding circuit configured to generate the plurality of first control signals based on a first delayed multi-bit digital signal with the first delay to the multi-bit digital signal, and
a second decoding circuit configured to generate the plurality of second control signals based on a second delayed multi-bit digital signal;
the first delay circuit is configured to generate the first delayed multi-bit digital signal with the first delay to the multi-bit digital signal; and
the second delay circuit is configured to generate the second delayed multi-bit digital signal with the second delay to the multi-bit digital signal.
